(19) United States
(12) Patent Application Publication
(10) Pub. No.: US 2014/0077355 A1
(43) Pub. Date: Mar. 20, 2014

(54) THREE-DIMENSIONAL SEMICONDUCTOR PACKAGE DEVICE HAVING ENHANCED SECURITY

(71) Applicants: Peter R. Harper, Gilroy, CA (US); Arkadii V. Samoilov, Saratoga, CA (US); Don Dias, Lewisville, TX (US)

(72) Inventors: Peter R. Harper, Gilroy, CA (US); Arkadii V. Samoilov, Saratoga, CA (US); Don Dias, Lewisville, TX (US)

(73) Assignee: MAXIM INTEGRATED PRODUCTS, INC., San Jose, CA (US)

(21) Appl. No.: 13/617,915

(22) Filed: Sep. 14, 2012

(51) Int. Cl. H01L 23/498; H01L 21/56

(52) U.S. Cl. 257/737; 438/126; 257/E23.068; 257/E21.502

(57) ABSTRACT

A semiconductor package device that includes an integrated circuit device package having a storage circuitry is disclosed. In an implementation, the semiconductor package device includes a semiconductor substrate having a first surface and a second surface. The semiconductor substrate includes one or more integrated circuits formed proximal to (e.g., adjacent to, in, or on) the first surface. The semiconductor package device also includes an integrated circuit device disposed over the second surface, the integrated circuit device including storage circuitry for storing sensitive data. In one or more implementations, the semiconductor package device includes a through-substrate via that furnishes an electrical connection to the integrated circuit package. The semiconductor package device also includes an encapsulation structure disposed over the second surface and at least substantially encapsulates the integrated circuit device package.

### BACKGROUND

A three-dimensional integrated circuit (3D IC) can be constructed using two or more layers of electronic components integrated into a single IC chip. The electronic components may be stacked to form a single electrical circuit. For example, two or more layers of active electronic components may be integrated both vertically and horizontally into a single circuit. Three-dimensional IC packaging processes are utilized to conserve space by stacking separate chips (e.g., die) into a single IC circuit package. Various types of manufacturing processes may be utilized to form the IC packages, which include monolithic packaging techniques, wafer-on-wafer packaging techniques, die-on-wafer packaging techniques, and die-on-die packaging techniques.

### SUMMARY

A semiconductor package device that includes an integrated circuit device package having a storage circuitry is disclosed. In an implementation, the semiconductor package device includes a semiconductor substrate having a first surface and a second surface. The semiconductor substrate includes one or more integrated circuits formed proximal to (e.g., adjacent to, in, or on) the first surface. The semiconductor package device also includes an integrated circuit device disposed over the second surface, the integrated circuit device including storage circuitry for storing sensitive data. In one or more implementations, the semiconductor package device includes a through-substrate via that furnishes an electrical connection to the integrated circuit package. The semiconductor package device also includes an encapsulation structure disposed over the second surface and at least substantially encapsulates the integrated circuit package device.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### DRAWINGS

The Detailed Description is described with reference to the accompanying figures. The use of the same reference numbers in different instances in the description and the figures may indicate similar or identical items.

FIG. 1A is a diagrammatic partial cross-sectional side elevation view illustrating a semiconductor package device in accordance with an example implementation of the present disclosure, where the semiconductor package device includes a substrate including one or more integrated circuits, an integrated circuit device positioned on the substrate, where the integrated circuit device includes a storage module for storing sensitive data.

FIG. 1B is a diagrammatic partial cross-sectional side elevation view illustrating a semiconductor package device in accordance with another example implementation of the present disclosure.

FIG. 2 is a flow diagram illustrating a process in an example implementation for fabricating integrated circuit devices having a storage module for storing sensitive data in accordance with the present disclosure.

FIGS. 3A through 3C are diagrammatic partial cross-sectional side elevation views illustrating the fabrication of an integrated circuit package device in accordance with the process shown in FIG. 2

FIG. 4 is a flow diagram illustrating a process in an example implementation for fabricating semiconductor package devices in accordance with the present disclosure, such as the device shown in FIG. 1A.

FIGS. 5A through 5C are diagrammatic partial cross-sectional side elevation views illustrating the fabrication of a wafer-level semiconductor package device, such as the device shown in FIG. 1A, in accordance with the process shown in FIG. 4.

### DETAILED DESCRIPTION

Overview

Consumers are storing additional sensitive data, such as user identification, bank account information, credit card information, passwords, and the like, in integrated circuit cards, such as smart cards. These consumers may utilize these integrated circuit cards to buy groceries, check-out books from a library, conduct financial transactions (e.g., Electronic Benefit Transfers (EBTs)), and so forth. Due to the sensitive nature of the information stored on these smart cards and the ease for which these cards can be stolen, securing this information is of utmost importance. Typically, integrated circuit cards may include storage circuitry positioned on a back side of an integrated circuit device. This type of device may be subjected to micro-probing, or the like, that would allow an unscrupulous person to retrieve and steal the consumer's sensitive information.

Accordingly, a semiconductor package device (e.g., a three-dimensional (3D) package device) that includes an integrated circuit device package having a storage circuitry is disclosed. The storage circuitry is configured to store sensitive data. In an implementation, the semiconductor package device includes a semiconductor substrate having a first surface and a second surface. The semiconductor substrate includes one or more integrated circuits formed proximal to (e.g., adjacent to, in, or on) the first surface. The semiconductor package device also includes an integrated circuit device disposed over the second surface, the integrated circuit device including storage circuitry for storing sensitive data. In one or more implementations, the semiconductor package device includes a through-substrate via that furnishes an electrical connection to the integrated circuit package. The semiconductor package device also includes an encapsulation structure disposed over the second surface and at least substantially encapsulates the integrated circuit device package. In an implementation, the integrated circuit device is configured to become non-operational when disassociated (e.g., electrically disconnected) from the semiconductor substrate, and the sensitive data is lost when the integrated circuit device becomes non-operational. In another implementation, the sensitive data may be lost when the semiconductor package device is subjected to a temperature utilized to de-process the semiconductor package device.

Example Implementations

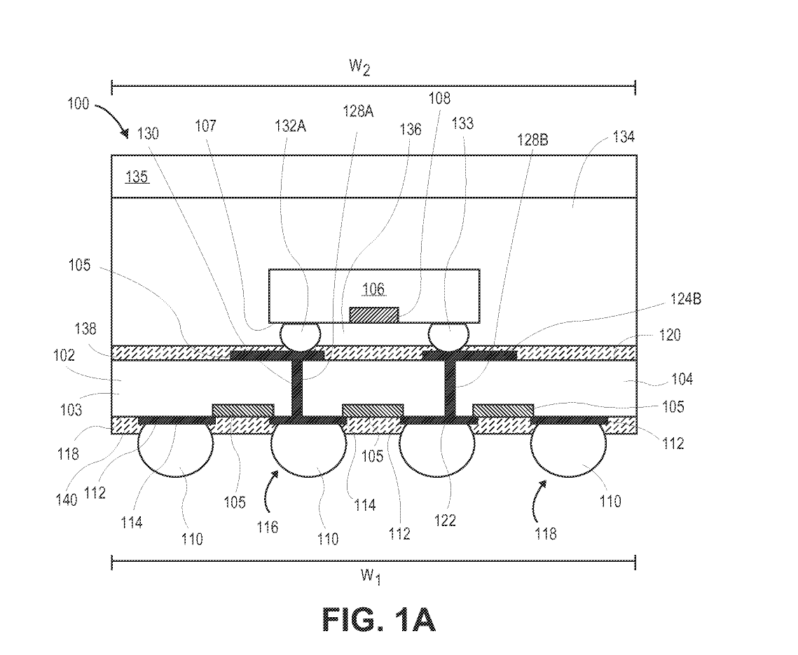

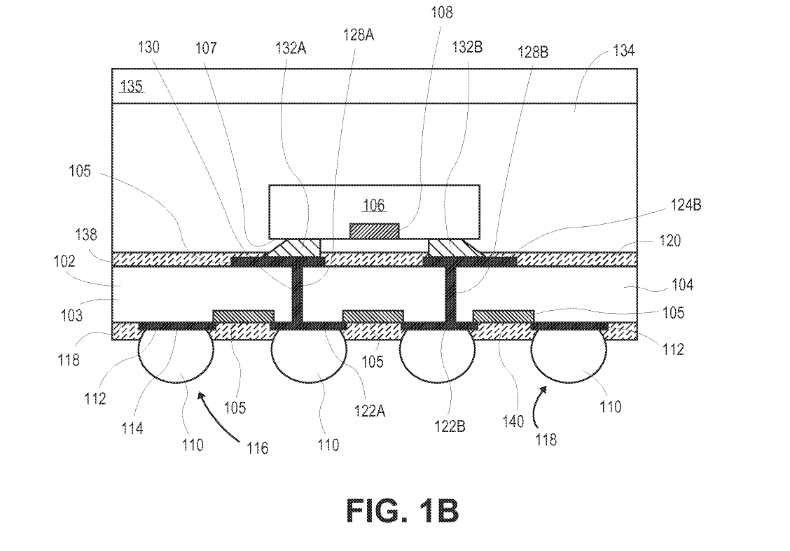

FIGS. 1A and 1B illustrate semiconductor package (WLP) devices that include one or more integrated circuit device packages. In an implementation, the integrated circuit device package includes a storage module (e.g., storage circuitry) configured to store sensitive data. For example, the semiconductor package devices are considered three-dimensional (3D) package assemblies as the devices include one or more dies that comprise a single semiconductor package device. The integrated circuit device package is configured to become non-operational in the event of unauthorized access to the WLP devices. For instance, the storage module is selectively positioned to be proximal to the backside of a substrate such that the integrated circuit device package becomes non-operational when subjected to a focused ion beam (FIB) process and/or micro-probing techniques.

Referring now to FIGS. 1A and 1B, a semiconductor package device 100 is described. The semiconductor package device 100 includes one or more dies (e.g., integrated circuit chip) 102 formed within a semiconductor substrate 103, such as a portion of a wafer 104. As described above, the die 102 includes integrated circuits 105 configured to furnish functionality to one or more host systems, and the like. In implementations, the integrated circuits may be comprised of digital circuitry, analog circuitry, combinations thereof, and so forth. The integrated circuits 105 may be connected to one or more conductive layers, such as contact pads, redistribution layers (RDLs) or the like, deployed over the die 102. These conductive layers provide electrical contacts through which the integrated circuits are interconnected to other components associated with the device 100 (e.g., printed circuit boards, etc.). The number and configuration of conductive layers (e.g., contact pads) may vary depending on the complexity and configuration of the integrated circuits, the size and shape of the die 102, and so forth.

As used herein, the term “semiconductor substrate” refers to substrates constructed of materials such as, but not limited to: silicon, silicon dioxide, aluminum oxide, sapphire, germanium, gallium arsenide (GaAs), alloys of silicon and germanium, and/or indium phosphide (InP). Further, for the purposes of the present disclosure, a semiconductor substrate can be formed as a semiconductor or an electrical insulator, and may include layers of both semiconducting and insulating material. For example, in implementations, a semiconductor substrate can be formed using an insulator, such as silicon oxide, with a layer of semiconducting material, such as silicon formed thereupon. Electrical components, such as transistors and diodes, can be fabricated in the semiconductor. In other implementations, the semiconductor substrate can be formed as an insulator, a dielectric, and so forth.

The semiconductor package device 100 also includes an integrated circuit device 106 (e.g., an integrated circuit die) positioned over the semiconductor substrate 103. The integrated circuit device 106 includes integrated circuits that may be comprised of digital circuitry, analog circuitry, combinations thereof, and so forth. In a specific implementation, the integrated circuit device 106 is configured as one or more integrated circuits configured to furnish security functionality (e.g., cause the device 106 to become non-operational when unauthorized access occurs) to the semiconductor package device 100. As described in greater detail below, the integrated circuit device 106 is in electrical communication with the integrated circuits 105. As shown in FIG. 1A, the integrated circuit device 106 includes a storage module 108 formed within the integrated circuit device 106. For instance, the storage module 108 may be formed proximal (e.g., adjacent to, in, on) the front side (e.g., surface 107) of the integrated circuit device 106. In an implementation, the storage module 108 comprises circuitry configured to store sensitive data (e.g., passwords, user identification, encryption codes, financial codes, user identification codes, or the like) therein. For example, the storage module 108 may comprise dynamic memory circuitry, such as random access memory (RAM) circuitry, configured to store the sensitive data while the storage module 108 is operational (e.g., a sufficient power supply is furnished to the storage module 108). Thus, unauthorized access to the semiconductor package device 100 may render the device 100 non-operational. For example, a focused ion beam (FIB) process and/or micro-probing techniques from the back side of the integrated circuit device 106 may render the circuitry within the device 106 non-operational, which in turn causes the storage module 108 to power down. In an implementation, the integrated circuit device 106 at least substantially encapsulates (e.g., encloses) the storage module 108. For example, the storage module 108 may be integral with the integrated circuit device 106.

As shown in FIGS. 1A and 1B, the semiconductor package device 100 includes a plurality of attachment bumps 110. The attachment bumps 110 comprise solder bumps that furnish mechanical and/or electrical interconnection between the contact pads deployed over the die 102 and corresponding pads formed on the surface of a printed circuit board. In one or more implementations, the attachment bumps 110 may be fabricated of a lead-free solder such as a Tin-Silver-Copper (Sn—Ag—Cu) alloy solder (i.e., SAC), a Tin-Silver (Sn—Ag) alloy solder, a Tin-Copper (Sn—Cu) alloy solder, and so on. However, it is contemplated that Tin-Lead (Pb—Sn) solders may be used. Example processes for forming the attachment bumps 110 using wafer-level packaging techniques are described in more detail below.

Bump interfaces 112 may be applied to the contact pads of the die 102 to provide a reliable interconnect boundary between the contact pads and the attachment bumps 110. For instance, in the semiconductor package device 100 shown in FIGS. 1A and 1B, the bump interface 112 comprises pad (e.g., redistribution) structures 114 applied to the contact pads of the integrated circuit chip 102. The pad structures 114 may have a variety of compositions. For example, the pad structures 114 may include multiple layers of different metals (e.g., Aluminum (Al), Nickel (Ni), Copper (Cu), Vanadium (V), Titanium (Ti), etc.) that function as an adhesion layer, a diffusion barrier layer, a solderable layer, an oxidation barrier layer, and so forth. However, other pillar structures are possible. In another implementation, the bump interfaces 112 may comprise under-ball metallization structures.

Viewed together, the attachment bumps 110 and associated bump interfaces 112 (e.g., pad structure 114) comprise bump assemblies 116 that are configured to provide mechanical and/or electrical interconnection of the die 102 to the printed circuit board. As illustrated in FIGS. 1A and 1B, the wafer-level package devices 100 may include one or more arrays 118 of bump assemblies 116 depending on various design considerations.

It is contemplated that the die (integrated circuit chip) 102 may include active circuitry (integrated circuits 105) proximate (e.g., adjacent) to the front side, or the surface 118, of the die 102. The front side is considered the surface 118 proximal to the bump assemblies 116 (e.g., distal to the integrated circuit device 106). Thus, the surface 120 is considered the passive surface, or back side (e.g., no active circuitry), of the die 102. The semiconductor package device 100 also includes one or more front side redistribution layers 122 deployed over the surface 118 (e.g., front side) and one or more back side redistribution layers 124 deployed over the surface 120 (e.g., back side). In this implementation, the redistribution layers 122 comprise the pad structures 114. However, it is understood that other configurations are possible (e.g., redistribution layers 122 and the pad structures 114 are distinct layers) according to the requirements of the devices 100. The redistribution layers 122, 124 include redistribution structure comprised of a thin-film metal (e.g., aluminum, copper) rerouting and interconnection system that redistributes the contact pads to an area array of electrical interfaces (e.g., bump interfaces 112, electrical interfaces 132, which are described in greater detail herein). As shown in FIGS. 1A and 1B, the front side (surface 107) of the integrated circuit device 106 is proximal to the back side (e.g., surface 120) of the substrate 103.

As shown, the integrated circuit device 106 is positioned over the surface 118 and electrically connected to the back side redistribution layers 124 (e.g., redistribution layers 124A, 124B). One or more of the back side redistribution layers 124 are electrically connected to one or more front side redistribution layers 122. In an implementation, the front side redistribution layers 122 (e.g., front side redistribution layers 122A, 122B) provide an electrical connection to the contact pads of the die 102, as well as to one or more bump assemblies 116. In a specific implementation, as shown in FIGS. 1A and 1B, the back side redistribution layers 124A, 124B are electrically connected to the front side redistribution layers 122A, 122B, respectively, by way of through-substrate vias (TSVs) 128 (TSVs 128A, 128B). In a specific implementation, the TSVs 128 may comprise micro-TSV structures. The TSVs 128 extend at least substantially through the substrate 103 (e.g., extend at least substantially the depth (D) of the substrate 103). In one or more implementations, the TSVs 128 have an aspect ratio of at least approximately 1:1 to at least approximately 10:1. The TSVs 128 include a conductive material 130, such as copper, poly-silicon, or the like, deposited therein. In a specific implementation, the TSVs 128 may have an approximate size (width) ranging from about fifty micrometers (50 um) to about 5 micrometers (Sum) and an approximate depth ranging from about fifty micrometers (50 um) to about one hundred micrometers (100 um).

The integrated circuit device 106 and the storage module 108 are communicatively connected to the respective redistribution layers 124 (124A, 124B) by way of an electrical interface 132. As shown in FIGS. 1A and 1B, the electrical interfaces 132 may be configured in a variety of ways. For example, as shown in FIG. 1A, the electrical interface 132 may comprise attachment bumps 133 that furnish an electrical connection between the integrated circuit device 106 and the corresponding redistribution layers 124. In another example, as shown in FIG. 1B, the electrical interface 132 may comprise an at least substantially non-spherical cross-sectional shape comprised of a solderable alloy, such as a tin-silver-copper (SnAgCu) alloy, a tin-lead (SnPb) alloy, or tin-antimony (Sn—Sb), Tin-alloy. In a specific implementation, the electrical interface 132 comprises a surface-mount pad for connecting the integrated circuit device 106 (as well as the storage module 108) to the corresponding redistribution layer 124. For instance, the flip chip pad can have a generally columnar shaped cross-sectional shape. However, it is understood that other cross-sectional shapes may be utilized (e.g., rectangular, square, oval, elliptical, etc.). It is contemplated that the electrical interface 132 may have a higher melting point as compared to the melting point of the attachment bumps 110 to at least substantially prevent reflow of the electrical interface 132 when the attachment bumps 110 are subjected to a reflow process. As shown in FIG. 1A, a first electrical interface 132A connects the integrated circuit device 106 to the redistribution layer 124A, and a second electrical interface 132B connects the integrated circuit device 106 to the redistribution layer 124B. Thus, the integrated circuit package device is communicatively connected to the front side redistribution layers 122A, 122B (as well as to the integrated circuits 105).

The device 100 further includes an encapsulation structure 134 that encapsulates, at least substantially, the integrated circuit device 106 and is supported by the die 102. In one or more implementations, the encapsulation structure 134 is configured to provide mechanical and/or environmental protection to the integrated circuit device 106 and the storage module 108. A mechanical stiffener assembly 135 may be used to provide mechanical strength and control flatness of the device 100. The stiffener assembly 135 may be comprised of a number of suitable materials, such as, but not limited to, a silicon material, an aluminum oxide (Al2O3) material, a ceramic material, or Alloy 42. The encapsulation structure 134 may comprise a mold compound (e.g., an overmold), a ceramic material, plastic, an epoxy material, or the like. The width (W1) of the encapsulation structure 134 is at least approximately the width (W2) of the die 102. The encapsulation structure 134 is also configured to prevent unwanted tampering with the integrated circuit device 106. By positioning the structure 134 over the surface 120 (back side) of the substrate 103, any un-authorized access by way of de-processing (e.g., de-soldering, etc.) the device 100 may also render the device 100 non-operational (e.g., causing the loss of the sensitive data). For example, removing the integrated circuit device 106 from the substrate 103 causes a break in the electrical connection between the device 106 and the substrate 103. This electrical connection break may cause the loss of power to the device 106, which causes a loss of the sensitive information. The operational status of the device 106 depends on an electrical connection to the substrate 103 (e.g., the device 106 is non-operational if disconnected from the substrate 103). Thus, in some implementations, when the integrated circuit device 106 becomes disassociated from the substrate 103, the sensitive data stored in the storage module 108 is lost (e.g., removed, etc.) Additionally, the sensitive data stored in the storage module 108 may be lost when the device 100 is subjected to temperatures utilized to de-process the device 100.

As shown, an underfill 136 at least partially encapsulates the electrical interfaces 132 and serves to furnish mechanical support and/or environmental protection to the electrical interfaces 132. The underfill 136 may be deposited at least partially over a first protective layer 138 (e.g., dielectric material, etc.). In an implementation, the underfill 136 may be filled epoxy or another suitable dielectric material. It is contemplated that a flip-chip process may be utilized to position the electrical interfaces 132 on the integrated circuit device 106 and to electrically connect the device 106 to the back side redistribution layer 124. Additionally, as shown in FIGS. 1A and 1B, the semiconductor package device 100 may also include a second protective layer 140 deposited over the surface 118 (e.g., front side) to at least partially provide mechanical support to the attachment bumps 110. The second protective layer 140 may comprise multiple polymer layers that serve to function as a stress buffer during fabrication of the substrate 103.

Example Fabrication Process

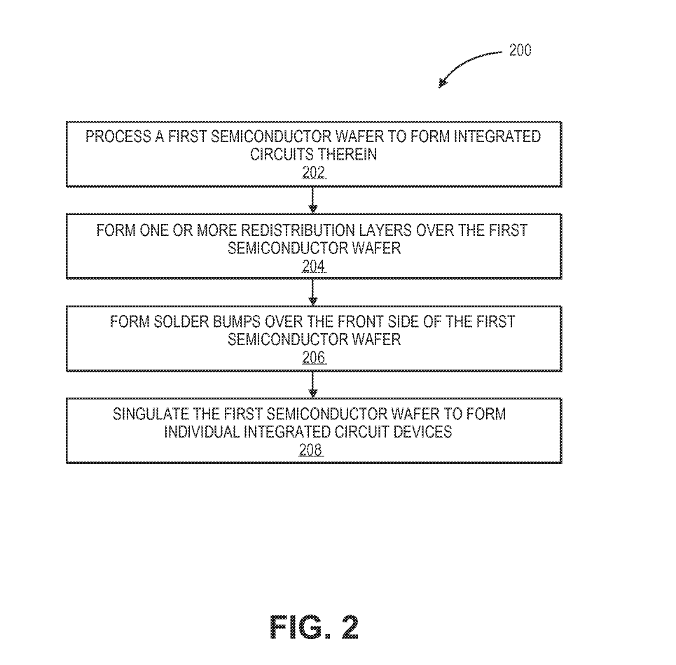

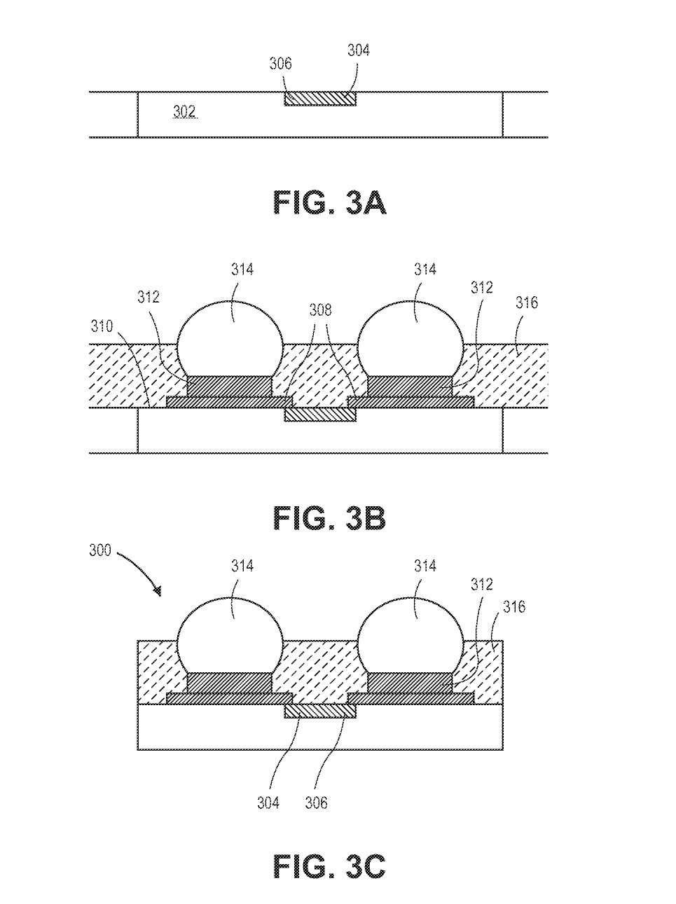

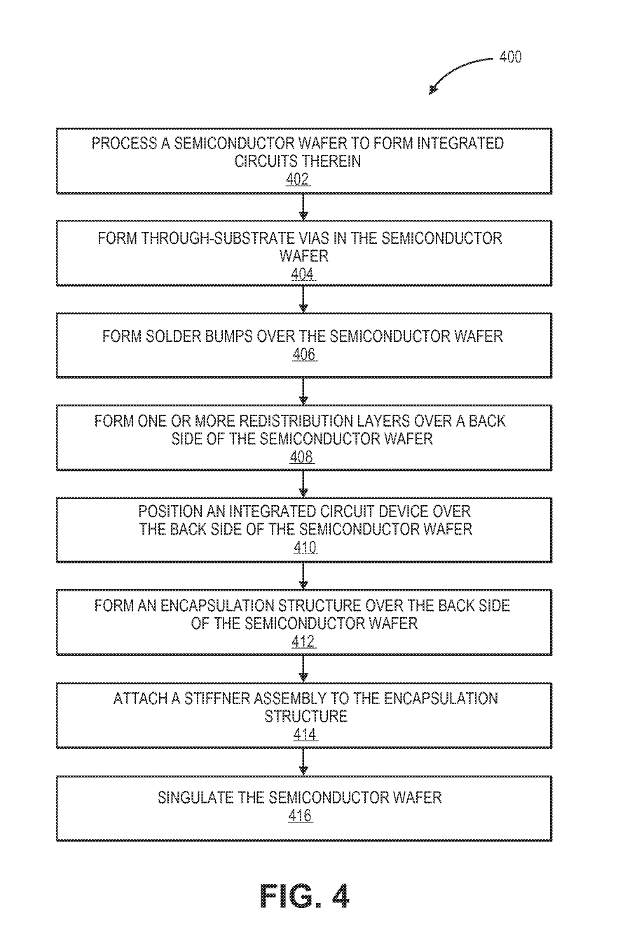

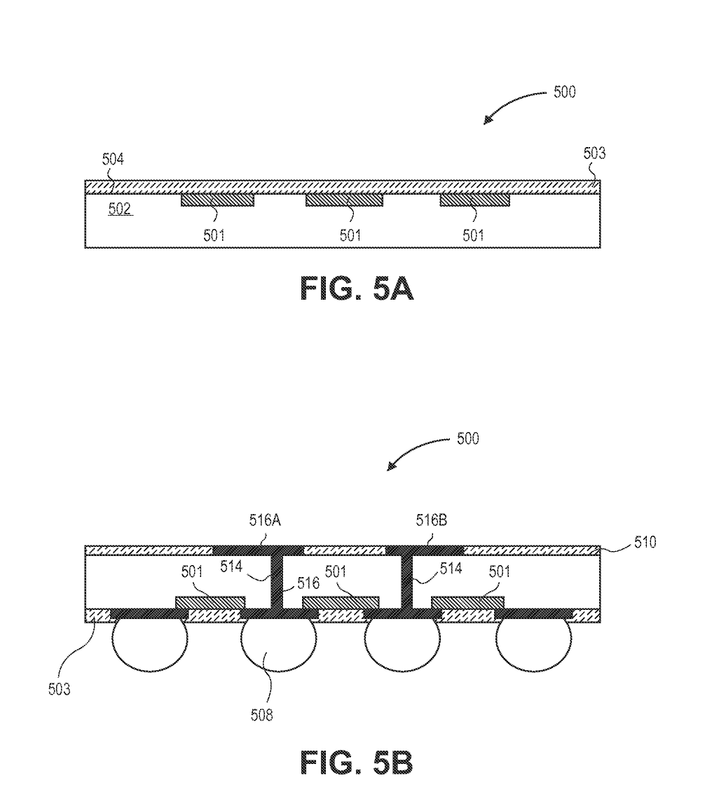

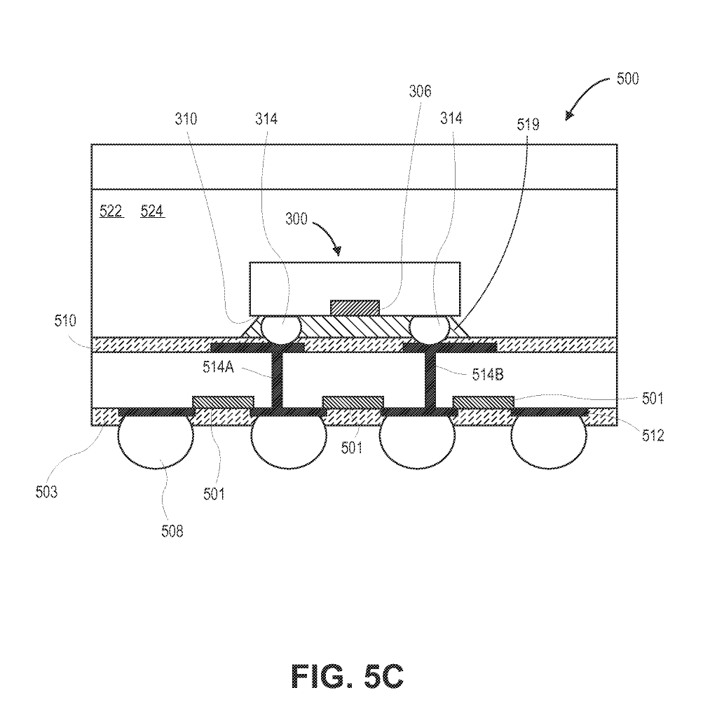

The following discussion describes example techniques for fabricating a semiconductor chip package including an integrated circuit device package therein, where the chip package is formed in a wafer level packaging (WLP) process. While a WLP process is described, it is understood that the present disclosure may be utilized in a Flip-Chip Ball Grid Array (FC-BGA) package configuration, a wire bond package configuration, or the like. FIG. 2 depicts a process 200 for fabricating an integrated circuit device, and FIG. 4 depicts a process 400, in an example implementation, for fabricating a semiconductor device, such as the example chip packages 100 illustrated in FIGS. 1A and 1B as described above. FIGS. 3A through 3C illustrate sections of example semiconductor wafers that are utilized to fabricate integrated circuit devices 300, such as integrated circuit device 106 shown in FIG. 1A. FIGS. 5A through 5C illustrate sections of example semiconductor wafers that are utilized to fabricate semiconductor devices 500 (such as device 100 shown in FIG. 1B).

In the process 200 illustrated, a first semiconductor wafer (e.g., substrate) is processed (Block 202) to form integrated circuits therein. As shown in FIG. 3A, a first semiconductor wafer 302 is processed utilizing front-end-of-line techniques to form integrated circuits 304 therein. One or more of the integrated circuits 304 is comprised to furnish storage functionality. For instance, as shown, the wafer 302 includes a storage module 306. In this implementation, one or more of the integrated circuits 304 comprise the storage module 306, which is configured to store sensitive data.

As shown in FIG. 2, one or more redistribution layers are formed over the first semiconductor wafer (Block 204). As shown in FIG. 3B, one or more redistribution layers 308 are formed (e.g., deposited) over a front side 310 of the wafer 302. Once the redistribution layers have been deposited, solder bumps are formed over the front side of the first semiconductor wafer (Block 206). In an implementation, as shown in FIG. 3B, solder balls are positioned over bump interfaces 312 (e.g., UBMs, front side redistribution layers, etc.) and reflowed to form solder bumps (e.g., attachment bumps) 314. As shown, the integrated circuit device 300 includes a protective layer 316 formed over the front side 310 of the wafer 302. Once the solder bumps have been formed, the first semiconductor wafer is singulated to form individual integrated circuit devices (Block 208). As shown in FIG. 3C, the integrated circuit devices 300 comprise individual die after singulation of the wafer 302. Once singulated, the integrated circuit devices 300 are positioned over a second semiconductor wafer for further processing steps, as described in greater detail below (see Block 410 of FIG. 4).

In the process 400 illustrated in FIG. 4, a second semiconductor wafer (e.g., substrate) is processed (Block 402) to form integrated circuits therein. The integrated circuits may be configured in a variety of ways. For example, the integrated circuits may be digital integrated circuits, analog integrated circuits, mixed-signal integrated circuits, and so forth. In one or more implementations, front-end-of-line techniques may be utilized to form the integrated circuits 501 in a second semiconductor wafer, such as the wafer 502 illustrated in FIG. 5A.

Through-substrate vias are formed within the semiconductor wafer (Block 404). As shown in FIG. 5B, a second protective layer 510 is formed (e.g., deposited) over the back (e.g., passive) side, or the surface 512, of the wafer 502. As shown, the wafer 502 has been flipped (e.g., a flip-chip process once the front side of the wafer 502 has been processed) to continue with fabrication of the device 500. The second protective layer 510 is then selectively etched to at least substantially remove portions of the protective layer 510. One or more micro-through-substrate (e.g., silicon) vias (TSVs) 514 are then formed within the semiconductor wafer and a conductive material 516 (e.g., copper, poly-silicon, etc.) deposited therein. Formation of the micro-TSVs 514 may include selective removing (via a suitable etching process) portions of the wafer 502 such that the TSVs 514 extend from the back side of the wafer 502 to the front side of the wafer 502. The TSVs 514 (514A, 514B) serve to provide electrical connectivity between the front side of the wafer and the back side of the wafer 502. The conductive material 516 may be deposited through suitable deposition processes, such as a copper damascene process, or the like. In a specific implementation, the micro-TSVs 514 may have an approximate size from about five micrometers (Sum) to about twenty micrometers (20 um) and an approximate depth from about fifty micrometers (50 um) to about one hundred micrometers (100 um).

Once the integrated circuits 501 are formed within the wafer 502, a protective layer (e.g., passivation layer, dielectric layer, etc.) 503 is formed over the wafer 502 to furnish protection to the integrated circuits during manufacturing and use. The protective layer 503 is formed over the front (e.g., active) side, or the surface 504, of the wafer 502. Once the protective layer is formed over the front side (surface) of the wafer, solder bumps are formed over the semiconductor wafer (Block 406). For example, solder balls are positioned over bump interfaces 506 (e.g., UBMs, front side redistribution layers, etc.) and reflowed to form solder bumps (e.g., attachment bumps) 508 (see FIG. 5B). In an implementation, the protective layer 503 is selectively etched prior to placement and formation of the solder bumps.

One or more redistribution layers are formed over the back side of the semiconductor wafer (Block 408). As shown in FIG. 5B, the redistribution layers 516A, 516B are deposited over the surface 512 of the wafer 502. Once the redistribution layers 516A, 516B are formed (deposited), the redistribution layers 516A, 516B may be selectively etched to prevent electrical crosstalk and/or electrical shorts. One or more integrated circuit devices (integrated circuit devices described with respect to FIGS. 2 and 3) are positioned over and in contact with the back side of the semiconductor wafer (Block 410). It is contemplated that various manufacturing techniques may be utilized to position the integrated circuit device package over the substrate including, but not limited to: wafer-on-wafer manufacturing techniques, die-on-wafer manufacturing techniques, and die-on-die manufacturing techniques. As shown in FIG. 5C, an integrated circuit device 300 is positioned over and in contact with the redistribution layers 516A, 516B. The integrated circuit device 300 is in electrical contact with the respective redistribution layers 516A, 516B by way of electrical interfaces 314 (solder bumps, etc.). An underfill 519 at least partially encapsulates the electrical interfaces 314 and serves to furnish mechanical support and/or environmental protection to the electrical interfaces 314. As shown, the integrated circuit device 300 is in electrical communication with the front side (e.g., integrated circuits 501 of the wafer 502, etc.) by way of the redistribution layers 516A, 516B, the TSVs 514, and the attachment interfaces 506. As shown, the integrated circuit device 300 includes a storage module 306 (e.g., storage circuitry) configured to store sensitive data, which is described in greater detail above.

An encapsulation structure is then formed over the semiconductor wafer over the back side of the semiconductor wafer (Block 412). An encapsulation structure, for example as shown in FIG. 5C the encapsulation structure 522, may comprise an overmold 524 (e.g., a mold compound). The mold compound may comprise a liquid material, such as an epoxy material, a resin based material, and/or a thermoplastic elastomer material. For example, in a specific instance, an epoxy backbone can be used with a spherical epoxy filler material. The mold compound may be selected based upon characteristics including, but not limited to: Coefficient of Thermal Expansion (CTE), flex modulus, and/or particle size.

In some embodiments, a transfer molding process can be used with the mold compound. In an embodiment, a liquid mold compound may be used to form the overmold 524. In other embodiments, a compression molding process can be used with the mold compound. For example, a granular mold compound is placed in a compression mold cavity, pressure is applied to the mold compound, and then heat and pressure are maintained until the molding material has cured. It should be noted that the thickness of the mold compound may be selected to prevent or minimize the effects of pressure upon the integrated circuit device 300. An stiffner assembly may then be attached to the encapsulation structure (Block 414). As described above, a stiffner assembly 526 may be attached to the encapsulation structure 522 to provide further mechanical support to the device 500. Next, the semiconductor substrate may be singulated to provide individual integrated circuit devices (Block 216). For example, wafer 502 can be singulated to provide individual chip packages, such as chip packages 100.

### CONCLUSION

Although the subject matter has been described in language specific to structural features and/or process operations, it is to be understood that the subject matter defined in the appended claims is not necessarily limited to the specific features or acts described above. Rather, the specific features and acts described above are disclosed as example forms of implementing the claims.

What is claimed is:

1. A semiconductor package device comprising:
a semiconductor substrate having a first surface and a second surface, the semiconductor substrate including one or more integrated circuits formed proximate to the first surface;
an integrated circuit device package disposed over the second surface, the integrated circuit device comprising storage circuitry for storing sensitive data; and
an encapsulation structure disposed over the second surface, the encapsulation structure at least substantially encapsulating the integrated circuit device package.

2. The semiconductor device as recited in claim 1, further comprising a through-substrate via at least substantially extending from the first surface to the second surface, the through-substrate via configured to electrically connect the integrated circuit device package to at least one of the one or more integrated circuits.

3. The semiconductor device as recited in claim 2, further comprising a redistribution layer formed over the second surface, the redistribution layer configured to furnish an electrical connection between the integrated circuit device package and the through-substrate via.

4. The semiconductor device as recited in claim 1, further comprising a plurality of attachment bumps disposed over the first surface.

5. The semiconductor device as recited in claim 4, wherein the plurality of attachment bumps comprises a plurality of solder bumps.

6. The semiconductor device as recited in claim 1, wherein the storage circuitry comprises dynamic storage circuitry configured to lose the sensitive data when the integrated circuit device becomes non-operational.

7. The semiconductor device as recited in claim 1, further comprising a stiffner assembly disposed over the encapsulation structure to provide mechanical strength to the encapsulation structure.

8. The semiconductor device as recited in claim 1, wherein the encapsulation structure is comprised of an overmold molded over the second surface of the semiconductor substrate.

9. A three-dimensional semiconductor package device comprising:
a semiconductor substrate having a first surface and a second surface, the semiconductor substrate including one or more integrated circuits formed proximate to the first surface;
an integrated circuit device package disposed over the second surface, the integrated circuit device package comprising storage circuitry for storing sensitive data;
an encapsulation structure disposed over the second surface, the encapsulation structure at least substantially encapsulating the integrated circuit device package; and
a through-substrate via at least substantially extending through the semiconductor substrate, the through-substrate via configured to electrically connect the integrated circuit device package to the one or more integrated circuits,
wherein the integrated circuit device package is configured to become non-operational when disassociated from the semiconductor substrate, wherein the sensitive data is lost when the integrated circuit device package becomes non-operational.

10. The semiconductor device as recited in claim 9, further comprising a redistribution layer formed over the second surface, the redistribution layer configured to furnish an electrical connection between the integrated circuit device package and the through-substrate via.

11. The semiconductor device as recited in claim 9, further comprising a plurality of attachment bumps disposed over the first surface, wherein at least one of the plurality of attachment bumps is electrically connected to the integrated circuit device package by way of the through-substrate via.

12. The semiconductor device as recited in claim 9, wherein the storage circuitry comprises dynamic storage circuitry configured to lose the sensitive data when the integrated circuit device becomes non-operational.

13. The semiconductor device as recited in claim 12, wherein the semiconductor substrate is electrically connected to the through-substrate via by way of one or more solder bumps disposed over the semiconductor substrate.

14. The semiconductor device as recited in claim 13, further comprising a plurality of attachment bumps disposed over the first surface, the plurality of attachment bumps having a first melting point and the one or more solder bumps having a second melting point, the second melting point higher than the first melting point.

15. A method of fabricating a wafer-level semiconductor package comprising:
processing a semiconductor wafer to form one or more integrated circuits therein, the semiconductor wafer having a first surface and a second surface, the one or more integrated circuits proximal to the first surface;
forming a through-substrate via in the semiconductor wafer, the through-substrate via extending at least substantially from the first surface to the second surface; and
positioning an integrated circuit device over the second surface, the integrated circuit device electrically connected to the one or more integrated circuits by way of the through-substrate via, the integrated circuit device comprising storage circuitry for storing sensitive data.

16. The method as recited in claim 15, further comprising:
forming a redistribution layer over the second surface, the redistribution layer electrically connected to the through-substrate via and the integrated circuit device; and
forming an encapsulation structure over the second surface, the encapsulation structure at least substantially encapsulating the integrated circuit device.

17. The method as recited in claim 16, wherein the encapsulation structure comprises an overmold molded over the second surface.

18. The method as recited in claim 16, further comprising attaching a stiffner assembly to the encapsulation structure.

19. The method as recited in claim 14, wherein the storage circuitry comprises dynamic storage circuitry configured to lose the sensitive data when the integrated circuit device becomes non-operational.

20. The method as recited in claim 14, wherein the integrated circuit device comprises an integrated circuit device package.
